(19) United States
(12) Patent Application Publication
(10) Pub. No.: US 2014/0090974 A1
(43) Pub. Date: Apr. 3, 2014

(54) TEMPERABLE AND NON-TEMPERABLE TRANSPARENT NANOCOMPOSITE LAYERS

(71) Applicants: Bart Ballet, Jumet (BE); Gaetan Di Stefano, Jumet (BE)

(72) Inventors: Bart Ballet, Jumet (BE); Gaetan Di Stefano, Jumet (BE)

(73) Assignee: AGC Glass Europe, Bruxelles (Watermael-Boitsfort) (BE)

(21) Appl. No.: 14/123,661

(22) PCT Filed: Jun. 28, 2012
(86) PCT No.: PCT/EP2012/062606

§ 371 Date: Dec. 3, 2013

(30) Foreign Application Priority Data
Jun. 30, 2011 (EP) 11172135.3

(51) Int. Cl. C23C 14/00

(52) U.S. Cl. CPC C23C 14/0057
USPC 204/192.15; 204/192.12

(57) ABSTRACT

The invention concerns a transparent substrate carrying a layer of a transparent dielectric nanocomposite, comprising a matrix of SiN_{y}O_{z}, y being in the range 0 to 4/3, z being in the range 0 to 2 and y and z not being equal to 0 simultaneously, said matrix including nanoparticles selected from the group consisting of aluminum nitrides, zirconium nitrides, titanium nitrides, aluminum oxides, zirconium oxides, zinc oxides, titanium oxides, tin oxides, tantalum oxides and mixtures thereof.

The present invention concerns magnetron sputtered temperable and non-temperable transparent nanocomposite layers and a method of making the same. In particular, it relates to layers comprising a nitride composite matrix including nanoparticles of a transparent material. Such layers may for example be part of “Low-e” coatings, on glass products. They may be prepared, for example, using SiH₄ precursor.

In the context of the invention, “nanoparticles” include particles with mean diameters of about several Angstroms, for instance 10 to 150 Å, preferably 10 to 100 Å, or representing solid solution of these particles in said matrix.

Low emissivity (Low-e) coatings on glass substrates are well known in the art. Typically they may contain n Ag layers, typically 1 or more (currently up to 3, but more are possible), that give IR reflective properties, and n+1 dielectric layers surrounding said n Ag layers.

The Ag layer or, of a different high conductive metal like Au and Cu, may be the main component to bring the IR reflective property of a coated glass product. Typically, the Ag layer is between 80 and 200 mg/m².

The choice of dielectric and IR reflective layers enable control of the aesthetics of the coated glass product. A neutral color, with a* and b* negative and well balanced values, is more appealing than any other coated glass colors in transmission as well as in outside reflection. These dielectric layers are transparent and need to give sufficient protection to the more vulnerable metal layer. Typically, the dielectric materials are TiO₂, ZnO, SnO₂, ZrO₂, Si₃N₄, AlN, or combinations like SnZnₓO_{y} or SiOₓN_{y}, i.e. all possible mixtures from SnO₂ to ZnO and SiO₂ to Si₃N₄ respectively.

When the final dielectric layer is the outermost layer of the stack, i.e. in contact with the external environment, it therefore has to fulfill specific requirements in terms of chemical, mechanical and in some cases, thermal durability. The need for high chemical and mechanical durability is shown in following examples: humidity during storage, corrosion of the coating (salts, acids by touching the coating), corrosion during overseas transport, scratch resistance during transport, cutting, grinding and assembly of the glass etc.

More coatings are currently also heat treated for safety reasons and regulatory requirements in certain countries. The coating should therefore also be able to withstand thermal treatments of the glass, which is typically a treatment of several minutes at 600° C.-750° C., preferably 650° C.-700° C., depending on the type of glass, thickness and composition of the coatings, type of heat desired treatment etc. Heat treatment can have a great effect on the properties of the coating, such as diffusion of materials through the stack and oxidation of metal or nitride layers. For example, Ti or TiN topcoats, i.e. outermost layers of the stack, are sometimes used to have better protection of temperable coatings. This layer will take up oxygen, transforming into TiO₂ and at the same time protecting the stack from too severe oxidation. Also carbon (C) is used as topcoat for better scratch resistance. After heat treatment, C disappears as CO₂ gas. The functional IR reflective Ag layer is also often protected by barrier layers like Ti or NiCr that can oxidize during heat treatment, while protecting the Ag layer against oxidation. Heat treatment thus has a huge impact on the properties of the coated glass.

A method that is currently widely used for making such Ag-based Low-e coatings is physical vapor deposition (PVD), more specifically magnetron sputtering. This method generates very performing coatings exhibiting very good opto-energetical properties, high selectivity, very low emissivity combined with high transparency and low reflection, with a very good homogeneity. The drawback of this technique is however the chemical and mechanical durability of the stack. Therefore, PVD coatings with Ag layers are generally protected in insulating glazing units (IGU) under protected atmosphere and controlled humidity. Efforts are also done to better protect the coatings during transport using for instance a thin plastic film that is removed for assembly.

Typical topcoats known in the art are Zr(Nₓ)O_{y}, SnSiₓO_{y}, ZnSnₓO_{y}, SnO₂, SiN_{X}, SiNₓ:Al, SiAlₓO_{y}N_{z}, TiN, TiN/C, TiN/SiO₂, TiO₂, and TiZrOₓ. SnO₂ and TiO₂ are known as topcoats for temperable stacks, but are not sufficiently blocking oxygen diffusion into the stacks and require blocking barriers inside the stack to protect for example silver layer against oxidation. The oxidation of these barriers leads to a change of optical properties during heat treatment. ZrNₓO_{y}, TiN, TiN/C and TiN/SiO₂ can only be used as “to be tempered” topcoats because they change properties upon heat treatment, providing for example an increase in transmission (Tv) due to the initially absorptive nature of the layers. The following prior art may be cited: WO 2006/048462 A3, WO 2004/071984 A1, US 2006/0105180 A1, EP 1663894 B1, EP 1736454 A3, WO 2009/115599 A1, WO 2009/115596 A1.

From this list, only ZnSnOₓ, SiO₂, SiNₓ and SiAlₓN_{y} are generally considered as topcoats for temperable and non temperable coatings for the above mentioned reasons. The preparation of SiO₂ magnetron sputtering process is however a complicated process due to low deposition rates (low efficiency) and flaking of the coating causing more defects in the coating, whereas ZnSnOₓ presents limited chemical and mechanical durability and SiN_{X} and SiAlₓN_{y} are presumed to have low resistance to humidity and scratch resistance, particularly scratches that are produced before tempering which tend to open up and become visible after tempering (FR 2 723 940 A1).

The current invention is intended to solve at least one of the before mentioned drawbacks by introducing new types of materials that may be obtained using a new technique, especially by using SiH₄ and N₂ (and O₂) reactive gas in magnetron sputtering process with target material X, forming SiXₓN_{y}O_{z} nanocomposite material.

According to one of its aspects, the present invention provides a transparent substrate carrying a layer of a transparent dielectric nanocomposite as defined by claim 1. Other claims define preferred and/or alternative aspects of the invention.

The invention concerns a transparent substrate carrying a layer of a transparent dielectric nanocomposite, comprising a matrix of SiN_{y}O_{z}, y being in the range 0 to 4/3, z being in the range 0 to 2 and y and z not being equal to 0 simultaneously, said matrix including nanoparticles selected from the group consisting of aluminum nitrides, zirconium nitrides, titanium nitrides, aluminum oxides, zirconium oxides, zinc oxides, titanium oxides, tin oxides, tantalum oxides and mixtures thereof.

The dielectric nanocomposite layer of the invention has the ability to improve mechanical and chemical properties and may provide, when necessary, resistance to thermal treatment. It may for instance be applied to a Low-e coating and provide an improved scratch resistance, evaluated according to the Dry Brush Test (ASTM D 2486).

For clarity, we use herein the wording “transparent” (either applied to the substrate or the nanocomposite layer or material) in its wider meaning, i.e. not opaque, for applications where it is necessary to see through the substrate and the layer. Some components considered by the present invention may indeed be partially absorbing (e.g. TiN).

Such a matrix may be SiO₂ or Si₃N₄ or any mixture thereof according to the respective values of y and z, knowing that the present invention does not encompass a pure Si matrix, i.e. without any O and N, meaning that y and z are never equal to 0 simultaneously. The preferred matrix is Si₃N₄.

As nanoparticles, a transparent material of the group consisting of aluminum nitrides, zirconium nitrides, titanium nitrides, aluminum oxides, zirconium oxides, zinc oxides, titanium oxides, tin oxides, tantalum oxides and mixtures thereof is used. Especially, such particles may preferably be TiO₂, ZrO₂, AlN, ZrN, TiN or any mixture thereof. AlN, ZrN and mixtures thereof may provide the best results as regards mechanical and chemical properties. The nanoparticles are thus chemically different from the matrix of the transparent dielectric nanocomposite layer.

Preferably, the mean diameter of nanoparticles is within the range 10 to 150 Å, preferably 10 to 100 Å or 10 to 60 Å.

According to an embodiment, the transparent substrate is carrying a multi-layered stack, the dielectric nanocomposite layer is then very advantageously a topcoat of said multi-layered stack, preferably being the outermost layer. This multi-layered stack may be a Low-e stack, including at least one IR reflective layer and/or at least one absorbing layer. More specifically, the multi-layered stack may include at least one IR reflective layer, such as silver, doped silver or copper, at least one dielectric layer, especially ZnO, SnO₂, Si₃N₄ or combination thereof, such as ZnSnOₓ (Zn/Sn: 52/48 wt %), at least one barrier layer above the IR reflective layer, such as Ti, NiCr or oxides thereof, and at least one epitaxial layer under the IR reflective layer which promotes quality thereof, essentially consisting in a Zn based oxide: ZnO, ZnO:Al, Al content being of from 0.1 to 15 at. %, or ZnSnOₓ (Zn/Sn: 90/10 wt %). More precisely, the IR reflective layer may be then deposited over the epitaxial layer, optionally in direct contact thereon. More preferably, the multi-layered stack includes in the following order at least: one dielectric layer, one epitaxial layer, one IR reflective layer, one barrier layer, one dielectric layer and the nanocomposite layer of the invention as topcoat layer. The preferred compounds of any of such layers are those above mentioned.

The at least one absorbing layer is preferably selected from the group consisting of NiCr, W, Ti, Zr, Nb, nitrides thereof and alloys thereof. The absorbing layer may be at any position in the multi-layered stack. When the multi-layered stack includes at least one IR reflective layer and at least one absorbing layer, said absorbing layer is preferably between the IR reflective layer and a dielectric layer, below or above the IR reflective layer.

Advantageously, the nanocomposite layer is heat treatable. This includes bending and tempering of glass. Generally a heat treatment is performed several minutes at a temperature of 550° C.-750° C., depending on the kind of treatment that is desired and the thickness and composition of the glass. The topcoat itself does not show significant haze or defects after the heat treatment. Optical change after tempering is preferably very limited: ΔE*<2, preferably ΔE*<1. ΔE* is defined as \sqrt{(Δa*)²+(Δb*)²+(ΔL*)²} with L*, a*, b* defined in the CIELAB color space system (illuminant D65, 10°) and Δ meaning the difference in measurements before and after baking. The layer also preferably does not have a negative influence on the heat resistance of the underlying coating, which may sometimes result in a non-desirable increase of haze or defects.

Due to the increased demand of tempered glass, a temperable topcoat that does not or only limitedly change its optical properties is a very interesting development. Since the color shift of the topcoat is very limited, it is possible to have a limited color shift of ΔE*<2, preferably ΔE*<1 for the complete stack. The stack is called “self matchable”.

The thickness value of the nanocomposite layer is preferably in the range 5 to 500 Å, more preferably in the range 20 to 100 Å.

The transparent substrate may be a glass substrate, such as clear glass or low iron glass, optionally colored, or even a polymeric material consisting essentially of polycarbonate or of poly(methylmethacrylate), provided that said material is appropriated to the used technology.

Such transparent dielectric nanocomposite layers may be characterized by XPS (general composition, no nanostructures), XRD (crystal phase), Raman spectroscopy, Rutherford Backscattering spectroscopy, NRA, and TEM methods commonly used.

According to another of its aspects, the present invention provides a method of depositing a thin film coating on a substrate as defined by claim 10.

This method uses a magnetron sputtering device and comprises:
providing a vacuum chamber having magnetron means and having a magnetron sputtering target including a first material,
providing means for positioning a substrate in said chamber spaced from said source,
directing a first reactive sputtering gas in the chamber comprising at least one of oxygen, nitrogen and carbon,
directing a second gas in the chamber comprising a second material selected from the group consisting of metals and metalloids, and
forming a coating comprising the first material, the second material and at least one of oxygen, nitrogen and carbon.

The implementation of the magnetron sputtering method and devices for carrying out the method is known in the art.

In known magnetron sputtering techniques, to deposit metals, argon gas (Ar) is used as inert working gas to sustain the plasma close to the target material (cathode). Ar⁺ ions are accelerated to the target and small particles, such as atoms, are released from the target material. These particles are then deposited on a substrate, such as glass. When oxide or nitride layers are desired, a method is to introduce a ‘reactive sputtering gas’ like O₂ or N₂, possibly in combination with Ar. The sputtered particles will then react on the target and on the surface of the substrate with this gas (which is also ionized in the plasma and accelerate to the target) leading to oxide or nitride layers on the substrate. Also other gasses may be used to deposit different materials, such as NH₃ for nitride layers and C₂H₂ or other hydrocarbons for carbides.

The present method is based on the same principle and uses a reactive sputtering gas comprising at least one of oxygen, nitrogen and carbon, for example O₂ or N₂ or a mixture thereof. Ar may additionally be injected into the chamber, mainly to increase the deposition rate.

In the magnetron sputtering method of the invention, another gas is also injected into the chamber: a gas comprising a material selected from the group consisting of metals and metalloids, for example SiH₄.

This method differs from known PECVD (Plasma Enhanced Chemical Vapor Deposition) methods mainly in that the coating formed by the present method comprises a material coming from a sputtering target, in addition to materials coming from the injected gases, whereas in PECVD processes, the coating is formed only of components originating from the injected gases.

The dielectric nanocomposite layer of the invention may be obtained by said magnetron sputtering method with the addition of SiH₄ as “second” gas.

For this purpose, in a magnetron sputtering method according to the invention, SiH₄ is used as an additional gas. This is a very reactive and pyrophoric gas that forms SiO₂ in contact with air in an exothermic reaction. A particular effect of this gas is that Si based layers can be formed without the need for a Si target. Together with Ar working gas for maintaining the plasma and the addition of other gasses like O₂ and N₂, materials like SiOₓ and SiNₓ can be produced. This technique has for main advantage that it allows to increase the deposition rates, in particular for SiOₓ. For regular magnetron sputtering processes, the sputtering rate of SiO₂ is not profitable. With this new technique, the deposition rate is brought to the same level as the regular materials deposited by sputtering process, like SnO₂ and ZnO; the improvement may be at least of about two times (up to 8 times has been observed at lab scale). Hydrogen, which is also apparent in silane, forms water with oxygen, therefore a water pump might be needed to remove the humidity from the coater.

Next to these two basic materials (SiOₓ and SiNₓ), which already present a big advantage to regular magnetron sputtering process, new materials with different microstructure and with improved chemical, mechanical and thermal properties can be produced. New properties can thus be given to coatings (e.g. temperable self matchable topcoat, temperable absorbent, damage resistance topcoat protection).

For this method, a certain target material is used that will be incorporated in the final coating.

As example, if silane is again used as first reactive gas together with Ar working gas and O2 or N2 as second reactive gasses, this leads to the formation of a SiNyOz composite layer (y being in the range 0 to 4/3, z being in the range 0 to 2 and y and z not being equal to 0 simultaneously) which has particles of the target material incorporated. Thus a composite material is produced. Depending on the kind of material that is added, gas ratios (Ar—N2—O2—SiH4), power on the target and working pressures, different properties can be given to the coating. For example, addition of ZrN or AlN particles, resulting from a Zr or Al metallic target, in the matrix of SiNyOz, can improve chemical and mechanical durability. As another example, addition of TiN particles, resulting from a Ti metallic target, in the matrix of SiNyOz, can provide to the layer more absorbance.

Typically, the power of the target is from 400 W to 4 kW, for a target surface area of 550 cm², this means a power density of about 0.5 to 8 W/cm², the pulse of the power is from 100 to 200 kHz. At industrial scale, the powers are much higher, they can be up to 150 kW; the power density is then about 2 or 5 times higher than those obtained at lab scale.

According to a preferred embodiment of the invention, a nanocomposite of Si₃N₄ including ZrN or AlN particles may be prepared using Ar with a flow rate of 20-40 sccm (standard cubic centimeters per minute), SiH₄ with a flow rate of 2-10 sccm and N₂ with a flow rate of 30-70 sccm. The process is preferably carried out using a working pressure in the range 3 to 6 mTorr. The power of the target is in the range 400 to 600 W, for a target surface area of 550 cm², this means a power density of about 0.7 to 1.2 W/cm², the pulse being from 100 and 200 kHz.

1. A transparent substrate carrying a layer of a transparent dielectric nanocomposite, comprising a matrix of SiN_{y}O_{z}, y being in the range 0 to 4/3, z being in the range 0 to 2 and y and z not being equal to 0 simultaneously, said matrix including nanoparticles selected from the group consisting of aluminum nitrides, zirconium nitrides, titanium nitrides, aluminum oxides, zirconium oxides, zinc oxides, titanium oxides, tin oxides, tantalum oxides and mixtures thereof.

2. The transparent substrate according to claim 1, wherein the matrix is SiO₂, Si₃N₄ or a mixture thereof.

3. The transparent substrate according to claim 1 or 2, wherein the nanoparticles are selected from the group consisting of ZrO₂, TiO₂, AlN, ZrN, TiN and mixtures thereof.

4. The transparent substrate according to any of claims 1 to 3, wherein the mean diameter value of nanoparticles is within the range 10 to 150 Å.

5. The transparent substrate according to any of claims 1 to 4, carrying a multi-layered stack, the layer of a transparent dielectric nanocomposite being a topcoat of said multi-layered stack.

6. The transparent substrate according to claim 5, wherein the multi-layered stack is a Low-e stack, including at least one IR reflective layer and/or at least one absorbing layer.

7. The transparent substrate according to any of claims 5 to 6, wherein the multi-layered stack includes in the following order at least: one dielectric layer, one epitaxial layer, one IR reflective layer, one barrier layer, one dielectric layer and the layer of a transparent dielectric nanocomposite as topcoat layer.

8. The transparent substrate according to any of claims 6 to 7, wherein the absorbing layer is selected from the group consisting of NiCr, W, Ti, Zr, Nb, nitrides thereof and alloys thereof.

9. The transparent substrate according to any of claims 4 to 8, wherein when the multi-layered stack is including at least one IR reflective layer and at least one absorbing layer, said absorbing layer is between the IR reflective layer and a dielectric layer, below or above the IR reflective layer.

10. A method of depositing a thin film coating on a substrate using a magnetron sputtering device, the method comprising:
providing a vacuum chamber having magnetron means and having a magnetron sputtering target including a first material,
providing means for positioning a substrate in said chamber spaced from said source,
directing a first reactive sputtering gas in the chamber comprising at least one of oxygen, nitrogen and carbon,
directing a second gas in the chamber comprising a second material selected from the group consisting of metals and metalloids, and
forming a coating comprising the first material, the second material and at least one of oxygen, nitrogen and carbon.

11. The method according to claim 10, wherein the method further comprises providing argon in the chamber.

12. The method according to any of claims 10 to 11, wherein the second gas is silane.

13. The method according to any of claims 10 to 12, wherein the magnetron sputtering target is a Zr or Al metallic target.

14. The method according to any of claims 10 to 13, wherein the first reactive sputtering gas is directed in the chamber at a flow rate in the range 30 to 70 sccm.

15. The method according to any of claims 10 to 14, wherein the second gas is directed in the chamber at a flow rate in the range 2 to 10 sccm.
